(19) United States
(12) Patent Application Publication
(10) Pub. No.: US 2012/0087200 A1
(43) Pub. Date: Apr. 12, 2012

(54) INTERNAL COLUMN ADDRESS GENERATING CIRCUIT AND SEMICONDUCTOR MEMORY DEVICE

(75) Inventors: Sang Hee LEE, Seoul (KR); Jeong Tae HWANG, Icheon-si (KR)

(73) Assignee: HYNIX SEMICONDUCTOR INC., Icheon-si (KR)

(21) Appl. No.: 13/159,821

(22) Filed: Jun. 14, 2011

(30) Foreign Application Priority Data
Oct. 8, 2010 (KR) 10-2010-0098094

(51) Int. Cl. G11C 8/12; G11C 8/06

(52) U.S. Cl. 365/230.03

(57) ABSTRACT

A semiconductor memory device includes first and second bank groups and an internal column address generating circuit. Each of the first and second bank groups includes at least one bank. The internal column address generating circuit converts a column address into a first internal column address and outputs the first internal column address through a first transmission line in response to a bank address if a read operation or a write operation is performed on a bank of the first bank group. Also, the internal column address generating circuit converts the column address into a second internal column address and outputs the second internal column address through a second transmission line in response to the bank address if a read operation or a write operation is performed on a bank of the second bank group.

### CROSS-REFERENCES TO RELATED APPLICATIONS

The present application claims priority under 35 U.S.C 119(a) to Korean Application No. 10-2010-0098094, filed on Oct. 8, 2010, in the Korean intellectual property Office, which is incorporated herein by reference in its entirety set forth in full.

### BACKGROUND

A semiconductor memory device may have an address path and a data path. Examples of address paths include a row address path for selecting a word line by a row address, a column address path for selecting one of output enable signals by a column address. The data path may transmit data to an external device through an input/output line sense amplifier and a data output buffer. An operation on the column address path (hereinafter referred to as ‘column operation’) is controlled by a column path circuit including a column decoder. The column path circuit decodes a column address, selectively activates one of output enable signals, and transmits data, loaded on a bit line selected by the activated output enable signal, to an input/output line.

In general, a semiconductor memory device such as a dynamic random access memory (DRAM) device includes a plurality of banks each including memory cells that are assigned the same address. The semiconductor memory device simultaneously outputs data of the same-address memory cells included in each bank. To this end, the column path circuit performs a column operation of decoding a column address, selectively activating one of output enable signals, and simultaneously transmitting data, loaded on a bit line selected from each bank by the activated output enable signal, to an input/output line.

In the column operation, the column address is converted into an internal column address and it is transmitted to each bank included in the semiconductor memory device. Here, the internal column address continues to toggle. Therefore, as the length of a transmission line transmitting the internal column address increases, or as the number of the transmission line transmitting the internal column address increases, the loading thereof increases, thus increasing the power consumption.

### SUMMARY

An embodiment of the present invention relates to an internal column address generating circuit and a semiconductor memory device that can reduce the power consumption by transmitting an internal column address through a selected transmission line according to an accessed bank.

In an exemplary embodiment of the present invention, a semiconductor memory device includes first and second bank groups each including at least one bank, and an internal column address generating circuit configured to convert a column address into a first internal column address and output the first internal column address through a first transmission line in response to a bank address if a read operation or a write operation is performed on a bank of the first bank group, and to convert the column address into a second internal column address and output the second internal column address through a second transmission line in response to the bank address if a read operation or a write operation is performed on a bank of the second bank group.

In another exemplary embodiment of the present invention, an internal column address generating circuit includes a selection signal generating unit configured to generate a selection signal in a read operation in response to a read bank address, and generate the selection signal in a write operation in response to a write bank address, and a selective output unit configured to selectively output a read column address as a first or second internal column address in the read operation in response to the selection signal, and selectively output a write column address as the first or second internal column address in the write operation in response to the selection signal.

### BRIEF DESCRIPTION OF THE DRAWINGS

The above and other aspects, features and other advantages will be more clearly understood from the following detailed description taken in conjunction with the accompanying drawings, in which:

FIG. 1 is a block diagram of a semiconductor memory device according to an exemplary embodiment of the present invention;

FIG. 2 is a block diagram of an internal column address generating circuit included in the semiconductor memory device illustrated in FIG. 1;

FIG. 3 is a circuit diagram of a selection signal generating unit included in the internal column address generating circuit illustrated in FIG. 2; and

FIG. 4 is a circuit diagram of a selective output unit included in the internal column address generating circuit illustrated in FIG. 2.

### DESCRIPTION OF SPECIFIC EMBODIMENTS

Hereinafter, embodiments of the present invention will be described with reference to accompanying drawings. However, the embodiments are for illustrative purposes only and are not intended to limit the scope of the invention.

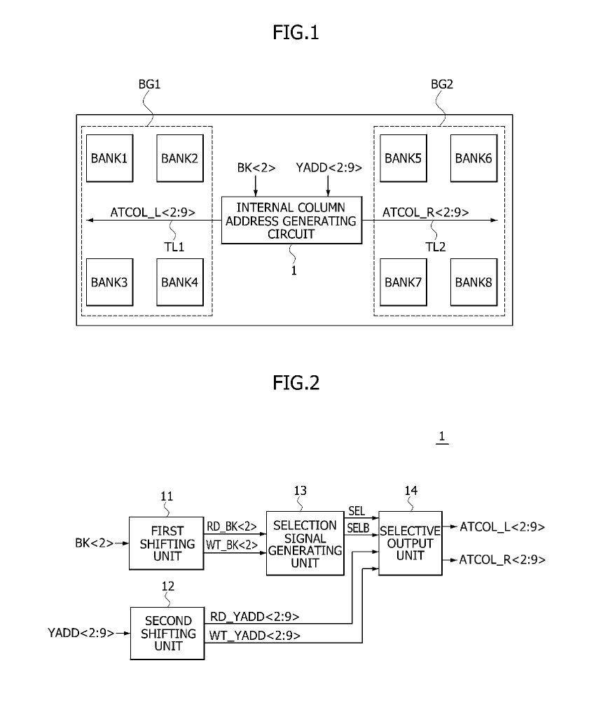

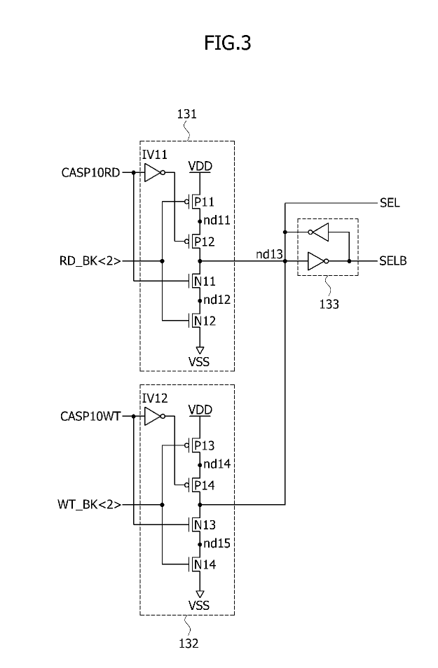

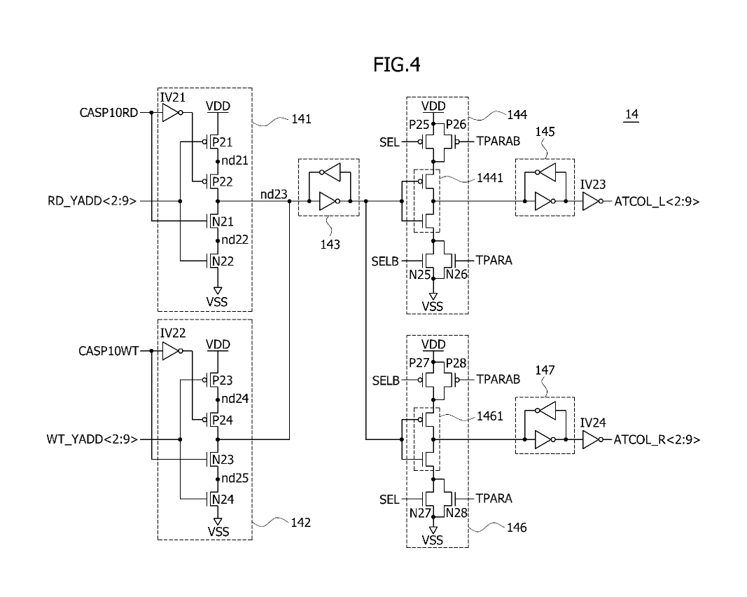

FIG. 1 is a block diagram of a semiconductor memory device according to an exemplary embodiment of the present invention. FIG. 2 is a block diagram of an internal column address generating circuit included in the semiconductor memory device illustrated in FIG. 1. FIG. 3 is a circuit diagram of a selection signal generating unit included in the internal column address generating circuit illustrated in FIG. 2. FIG. 4 is a circuit diagram of a selective output unit included in the internal column address generating circuit illustrated in FIG. 2.

Referring to FIG. 1, a semiconductor memory device according to an exemplary embodiment of the present invention includes a first bank group BG1, a second bank group BG2, and an internal column address generating circuit 1. The first bank group BG1 includes first to fourth banks BANK1, . . . , BANK4, and the second bank group BG2 includes fifth to eighth banks BANK5, . . . , BANK8. The internal column address generating circuit 1 is configured to convert a column address YADD<2:9> into a first internal column address ATCOL_L<2:9> and output the first internal column address ATCOL_L<2:9> through a first transmission line TL1 in response to a bank address BK<2>, and to convert the column address YADD<2:9> into a second internal column address ATCOL_R<2:9> and output the second internal column address ATCOL_R<2:9> through a second transmission line TL2 in response to the bank address BK<2>. Here, the internal column address generating circuit 1 may be located between the first bank group BG1 and the second bank group BG2. The first transmission line TL1 may be arranged toward the first bank group BG1, and the second transmission line TL2 may be arranged toward the second bank group BG2.

Referring to FIG. 2, the internal column address generating circuit 1 includes a first shifting unit 11, a second shifting unit 12, a selection signal generating unit 13, and a selective output unit 14.

The first shifting unit 11 is configured to shift the bank address BK<2> to a read operation time point and generate a read bank address RD_BK<2>, and to shift the bank address BK<2> to a write operation time point and generate a write bank address WT_BK<2>. Here, according to an example, the bank address BK<2> is applied at a logic high level if a read operation or a write operation is performed on the first bank group BG1. Also, the bank address BK<2> is applied at a logic low level if a read operation or a write operation is performed on the second bank group BG2.

The second shifting unit 12 is configured to shift the column address YADD<2:9> to a read operation time point and generate a read column address RD_YADD<2:9>, and to shift the column address YADD<2:9> to a write operation time point and generate a write column address WT_YADD<2:9>.

Referring to FIG. 3, the selection signal generating unit 13 includes a first driving unit 131, a second driving unit 132, and a first latch unit 133.

The first driving unit 131 includes PMOS transistors P11 and P12, NMOS transistors N11 and N12, and an inverter IV11 configured to invert and buffer a read enable signal CASP10RD. The PMOS transistor P11 is connected between a power supply voltage VDD and a node nd11. In response to the read bank address RD_BK<2>, the PMOS transistor P11 pulls up a voltage level of a node nd13. The PMOS transistor P12 is connected between the node nd11 and the node nd13. In response to an output signal of the inverter IV11, the PMOS transistor P12 pulls up the voltage level of the node nd13. The NMOS transistor N11 is connected between the node nd13 and a node nd12. In response to the read enable signal CASP10RD, the NMOS transistor N11 pulls down the voltage level of the node nd13. The NMOS transistor N12 is connected between the node nd12 and a ground voltage VSS. In response to the logic-high read bank address RD_BK<2>, the NMOS transistor N12 pulls down the voltage level of the node nd13.

The second driving unit 132 includes PMOS transistors P13 and P14, NMOS transistors N13 and N14, and an inverter IV12 configured to invert and buffer a write enable signal CASP10WT. The PMOS transistor P13 is connected between the power supply voltage VDD and a node nd14. In response to the logic-low write bank address WT_BK<2>, the PMOS transistor P13 pulls up the voltage level of the node nd13. The PMOS transistor P14 is connected between the node nd14 and the node nd13. In response to an output signal of the inverter IV12, the PMOS transistor P14 pulls up the voltage level of the node nd13. The NMOS transistor N13 is connected between the node nd13 and a node nd15. In response to the write enable signal CASP10WT, the NMOS transistor N13 pulls down the voltage level of the node nd13. The NMOS transistor N14 is connected between the node nd15 and the ground voltage VSS. In response to the logic-high write bank address WT_BK<2>, the NMOS transistor N14 pulls down the voltage level of the node nd13.

The first latch unit 133 is configured to invert/buffer a selection signal SEL outputted from the node nd13, output an inverted selection signal SELB, and latch the selection signal SEL and the inverted selection signal SELB.

Referring to FIG. 4, the selective output unit 14 includes a third driving unit 141, a fourth driving unit 142, a second latch unit 143, a first selective buffer unit 144, a third latch unit 145, a second selective buffer unit 146, a fourth latch unit 147, and inverters IV23 and IV24.

The third driving unit 141 includes PMOS transistors P21 and P22, NMOS transistors N21 and N22, and an inverter IV21 configured to invert and buffer the read enable signal CASP10RD. The PMOS transistor P21 is connected between the power supply voltage VDD and a node nd21. In response to the read column address RD_YADD<2:9>, the PMOS transistor P21 pulls up a voltage level of a node nd23. The PMOS transistor P22 is connected between the node nd21 and the node nd23. In response to an output signal of the inverter IV21, the PMOS transistor P22 pulls up the voltage level of the node nd23. The NMOS transistor N21 is connected between the node nd23 and a node nd22. In response to the read enable signal CASP10RD, the NMOS transistor N21 pulls down the voltage level of the node nd23. The NMOS transistor N22 is connected between the node nd22 and the ground voltage VSS. In response to the read column address RD_YADD<2:9>, the NMOS transistor N22 pulls down the voltage level of the node nd23.

The fourth driving unit 142 includes PMOS transistors P23 and P24, NMOS transistors N23 and N24, and an inverter IV12 configured to invert and buffer the write enable signal CASP10WT. The PMOS transistor P23 is connected between the power supply voltage VDD and a node nd24. In response to the write column address WT_YADD<2:9>, the PMOS transistor P23 pulls up the voltage level of the node nd23. The PMOS transistor P24 is connected between the node nd24 and the node nd23. In response to an output signal of the inverter IV22, the PMOS transistor P24 pulls up the voltage level of the node nd23. The NMOS transistor N23 is connected between the node nd23 and a node nd25. In response to the write enable signal CASP10WT, the NMOS transistor N23 pulls down the voltage level of the node nd23. The NMOS transistor N24 is connected between the node nd25 and the ground voltage VSS. In response to the write column address WT_YADD<2:9>, the NMOS transistor N24 pulls down the voltage level of the node nd23.

The second latch unit 143 is configured to receive and latch a signal of the node nd23.

The first selective buffer unit 144 includes a first buffer unit 1441, PMOS transistors P25 and P26, NMOS transistors N25 and N26. The first buffer unit 1441 is configured to invert and buffer an output signal of the second latch unit 143. The PMOS transistor P25 is connected between the power supply voltage VDD and the first buffer unit 1441 to operate as a switch that is turned on in response to the select signal SEL. The PMOS transistor P26 is connected between the power supply voltage VDD and the first buffer unit 1441 to operate as a switch that is turned on in response to an inverted parallel test signal TPARAB. The NMOS transistor N25 is connected between the first buffer unit 1441 and the ground voltage VSS to operate as a switch that is turned on in response to the inverted select signal SELB. The NMOS transistor N26 is connected between the first buffer unit 1441 and the ground voltage VSS to operate as a switch that is turned on in response to the parallel test signal TPARA. Here, the parallel test signal TPARA is applied at a logic high level in a parallel test mode.

The third latch unit 145 is configured to latch an output signal of the first buffer unit 1441. The inverter IV23 is configured to invert/buffer an output signal of the third latch unit 145 and output the first internal column address ATCOL_L<2:9>.

The second selective buffer unit 146 includes a second buffer unit 1461, a PMOS transistor P27, a PMOS transistor P28, an NMOS transistor N27, and an NMOS transistor N28. The second buffer unit 1461 is configured to invert and buffer an output signal of the second latch unit 143. The PMOS transistor P27 is connected between the power supply voltage VDD and the second buffer unit 1461 to operate as a switch that is turned on in response to the inverted select signal SELB. The PMOS transistor P28 is connected between the power supply voltage VDD and the second buffer unit 1461 to operate as a switch that is turned on in response to the inverted parallel test signal TPARAB. The NMOS transistor N27 is connected between the second buffer unit 1461 and the ground voltage VSS to operate as a switch that is turned on in response to the select signal SEL. The NMOS transistor N28 is connected between the second buffer unit 1461 and the ground voltage VSS to operate as a switch that is turned on in response to the parallel test signal TPARA.

The fourth latch unit 147 is configured to latch an output signal of the second buffer unit 1461. The inverter IV24 is configured to invert/buffer an output signal of the fourth latch unit 147 and output the second internal column address ATCOL_R<2:9>.

The operation of the semiconductor memory device may be divided into the case of a read operation and the case of a write operation, as follows.

Hereinafter, a description will be give of an operation of the semiconductor memory device in the case of a read operation.

In the read operation, the first shifting unit 11 shifts the bank address BK<2> to the read operation time point to generate the read bank address RD_BK<2>, and the second shifting unit 12 shifts the column address YADD<2:9> to the read operation time point to generate the read column address RD_YADD<2:9>.

In response to the read enable signal CASP10RD activated to a logic high level in the read operation, the first driving unit 131 of the selection signal generating unit 13 is driven to invert/buffer the read bank address RD_BK<2> prior to output. Thus, if a read operation is performed on the first bank group BG1, because the first driving unit 131 inverts/buffers the logic-high read bank address RD_BK<2>, the logic-low selection signal SEL is outputted from the node nd13. Also, if a read operation is performed on the second bank group BG2, because the first driving unit 131 inverts/buffers the logic-low read bank address RD_BK<2>, the logic-high selection signal SEL is outputted from the node nd13.

In response to the read enable signal CASP10RD activated to a logic high level in the read operation, the third driving unit 141 of the selective output unit 14 invert the level of the read column address RD_YADD<2:9>, and output the inverted read column address RD_YADD<2:9> to the node nd23. Here, a signal of the node nd23 driven by the third driving unit 141 is inverted/buffered and latched by the second latch unit 143.

Here, the first selective buffer unit 144 and the second selective buffer unit 146 of the selective output unit 14 are selectively driven according to the level of the selection signal SEL. That is, if a read operation is performed on the first bank group BG1, the first selective buffer unit 144 is driven to invert/buffer an output signal of the second latch unit 143 prior to output, and if a read operation is performed on the second bank group BG2, the second selective buffer unit 146 is driven to invert/buffer an output signal of the second latch unit 143 prior to output.

That is, if a read operation is performed on the first bank group BG1, the selective output unit 14 inverts/buffers the read column address RD_YADD<2:9> to generate the first internal column address ATCOL_L<2:9>. The first internal column address ATCOL_L<2:9> is transmitted through the first transmission line TL1 to the first bank group BG1. On the other hand, if a read operation is performed on the second bank group BG2, the selective output unit 14 inverts/buffers the read column address RD_YADD<2:9> to generate the second internal column address ATCOL_R<2:9>. The second internal column address ATCOL_R<2:9> is transmitted through the second transmission line TL2 to the second bank group BG2.

Hereinafter, a description will be give of an operation of the semiconductor memory device in the case of a write operation.

In the write operation, the first shifting unit 11 shifts the bank address BK<2> to the write operation time point to generate the write bank address WT_BK<2>, and the second shifting unit 12 shifts the column address YADD<2:9> to the write operation time point to generate the write column address WT_YADD<2:9>.

In response to the write enable signal CASP10WT activated to a logic high level in the write operation, the second driving unit 132 of the selection signal generating unit 13 is driven to invert/buffer the write bank address WT_BK<2> prior to output. Thus, if a write operation is performed on the first bank group BG1, because the second driving unit 132 inverts/buffers the logic-high write bank address WT_BK<2>, the logic-low selection signal SEL is outputted from the node nd13. Also, if a write operation is performed on the second bank group BG2, because the second driving unit 132 inverts/buffers the logic-low write bank address WT_BK<2>, the logic-high selection signal SEL is outputted from the node nd13.

In response to the write enable signal CASP10WT activated to a logic high level in the write operation, the fourth driving unit 142 of the selective output unit 14 invert the level of the write column address WT_YADD<2:9>, and output the inverted write column address WT_YADD<2:9> to the node nd23. Here, a signal of the node nd23 driven by the fourth driving unit 142 is inverted/buffered and latched by the second latch unit 143.

Here, the first selective buffer unit 144 and the second selective buffer unit 146 of the selective output unit 14 are selectively driven according to the level of the selection signal SEL. That is, if a write operation is performed on the first bank group BG1, the first selective buffer unit 144 is driven to invert/buffer an output signal of the second latch unit 143 prior to output and if a write operation is performed on the second bank group BG2, the second selective buffer unit 146 is driven to invert/buffer an output signal of the second latch unit 143 prior to output.

That is, if a write operation is performed on the first bank group BG1, the selective output unit 14 inverts/buffers the write column address WT_YADD<2:9> to generate the first internal column address ATCOL_L<2:9>. The first internal column address ATCOL_L<2:9> is transmitted through the first transmission line TL1 to the first bank group BG1. On the other hand, if a write operation is performed on the second bank group BG2, the selective output unit 14 inverts/buffers the write column address WT_YADD<2:9> to generate the second internal column address ATCOL_R<2:9>. The second internal column address ATCOL_R<2:9> is transmitted through the second transmission line TL2 to the second bank group BG2.

As described above, the semiconductor memory device according to the exemplary embodiment of the present invention transmits the first internal column address ATCOL_L<2:9>, for example, only through the first transmission line TL1 if a read or write operation is performed on the first bank group BG1 by the internal column address generating circuit 1 located between the first bank group BG1 and the second bank group BG2, and transmits the second internal column address ATCOL_R<2:9>, for example, only through the second transmission line TL2 if a read or write operation is performed on the second bank group BG2. The first transmission line TL1 and the second transmission line TL2 selectively transmit the column address and can be formed to be shorter than those of the case of transmitting the column address of all the banks, thus the power consumption for the column address transmission may decrease.

The embodiments of the present invention have been disclosed above for illustrative purposes. Those skilled in the art will appreciate that various modifications, additions and substitutions are possible, without departing from the scope and spirit of the invention as disclosed in the accompanying claims.

What is claimed is:

1. A semiconductor memory device comprising:
first and second bank groups each comprising at least one bank; and
an internal column address generating circuit configured to convert a column address into a first internal column address and output the first internal column address through a first transmission line in response to a bank address if a read operation or a write operation is performed on a bank of the first bank group, and to convert the column address into a second internal column address and output the second internal column address through a second transmission line in response to the bank address if a read operation or a write operation is performed on a bank of the second bank group.

2. The semiconductor memory device of claim 1, wherein the internal column address generating circuit is located between the first bank group and the second bank group.

3. The semiconductor memory device of claim 2, wherein the first transmission line is arranged toward the first bank group, and the second transmission line is arranged toward the second bank group.

4. The semiconductor memory device of claim 1, wherein if the bank address is at a first level, the internal column address generating circuit outputs the first internal column address through the first transmission line, and if the bank address is at a second level, the internal column address generating circuit outputs the second internal column address through the second transmission line.

5. The semiconductor memory device of claim 1, wherein the internal column address generating circuit generates a selection signal in response to the bank address, and converts the column address into the first internal column address or the second internal column address in response to the selection signal.

6. The semiconductor memory device of claim 5, wherein the internal column address generating circuit comprises:
a selection signal generating unit configured to generate a selection signal in response to a read bank address; and
a selective output unit configured to selectively output a read column address as a first or second internal column address in response to the selection signal.

7. The semiconductor memory device of claim 6, further comprising:
a first shifting unit configured to shift the bank address to a read operation time point and generate the read bank address; and
a second shifting unit configured to shift the column address to the read operation time point and generate the read column address.

8. The semiconductor memory device of claim 6, wherein the selection signal generating unit comprises a driving unit configured to drive the selection signal in response to the read bank address and a read enable signal activated at a read operation time point.

9. The semiconductor memory device of claim 8, wherein the selection signal generating unit further comprises a latch unit configured to buffer the selection signal, generate an inverted selection signal, and latch the selection signal and the inverted selection signal.

10. The semiconductor memory device of claim 6, wherein the selective output unit comprises:
a driving unit configured to drive a first node in response to the read column address and a read enable signal activated at a read operation time point; and
a selective buffer unit configured to buffer a signal of the first node and output the buffered signal to a second node in response to the selection signal and a parallel test signal.

11. The semiconductor memory device of claim 10, wherein the selective output unit further comprises:
a latch unit configured to latch a signal of the second node; and
a buffer configured to buffer an output signal of the latch unit and output the first internal column address.

12. The semiconductor memory device of claim 5, wherein the internal column address generating circuit comprises:
a selection signal generating unit configured to generate a selection signal in response to a write bank address; and
a selective output unit configured to selectively output a write column address as a first or second internal column address in response to the selection signal.

13. The semiconductor memory device of claim 12, further comprising:
a first shifting unit configured to shift the bank address to a write operation time point and generate the write bank address; and
a second shifting unit configured to shift the column address to the write operation time point and generate the write column address.

14. The semiconductor memory device of claim 12, wherein the selection signal generating unit comprises a driving unit configured to drive the selection signal in response to the write bank address and a write enable signal activated at a write operation time point.

15. The semiconductor memory device of claim 14, wherein the selection signal generating unit further comprises a latch unit configured to buffer the selection signal, generate an inverted selection signal, and latch the selection signal and the inverted selection signal.

16. The semiconductor memory device of claim 12, wherein the selective output unit comprises:
a driving unit configured to drive a first node in response to the write column address and a write enable signal activated at a write operation time point; and
a selective buffer unit configured to buffer a signal of the first node and output the buffered signal to a second node in response to the selection signal and a parallel test signal.

17. The semiconductor memory device of claim 16, wherein the selective output unit further comprises:
a latch unit configured to latch a signal of the second node; and
a buffer configured to buffer an output signal of the latch unit and output the second internal column address.

18. An internal column address generating circuit comprising:
a selection signal generating unit configured to generate a selection signal in a read operation in response to a read bank address, and generate the selection signal in a write operation in response to a write bank address; and
a selective output unit configured to selectively output a read column address as a first or second internal column address in the read operation in response to the selection signal, and selectively output a write column address as the first or second internal column address in the write operation in response to the selection signal.

19. The internal column address generating circuit of claim 18, further comprising:
a first shifting unit configured to shift the bank address to a read operation time point and generate the read bank address, and to shift the bank address to a write operation time point and generate the write bank address; and
a second shifting unit configured to shift the column address to the read operation time point and generate the read column address, and to shift the column address to the write operation time point and generate the write column address.

20. The internal column address generating circuit of claim 18, wherein the selection signal generating unit comprises:
a first driving unit configured to drive the selection signal in response to the read bank address and a read enable signal activated at a read operation time point; and
a second driving unit configured to drive the selection signal in response to the write bank address and a write enable signal activated at a write operation time point.

21. The internal column address generating circuit of claim 20, wherein the selection signal generating unit further comprises a latch unit configured to buffer the selection signal, generate an inverted selection signal, and latch the selection signal and the inverted selection signal.

22. The internal column address generating circuit of claim 18, wherein the selective output unit comprises:
a first driving unit configured to drive a first node in response to the read column address and a read enable signal activated at a read operation time point;
a first selective buffer unit configured to buffer a signal of the first node and output the same to a second node in response to the selection signal and a parallel test signal;
a second driving unit configured to drive the first node in response to the write column address and a write enable signal activated at a write operation time point; and
a second selective buffer unit configured to buffer a signal of the first node and output the same to a third node in response to the selection signal and the parallel test signal.

23. The internal column address generating circuit of claim 22, wherein the selective output unit further comprises:
a first latch unit configured to latch a signal of the second node;
a first buffer configured to buffer an output signal of the first latch unit and output the first internal column address;
a second latch unit configured to latch a signal of the third node; and
a second buffer configured to buffer an output signal of the second latch unit and output the second internal column address.
